(19) United States
(12) Patent Application Publication
(10) Pub. No.: US 2025/0193872 A1
(43) Pub. Date: Jun. 12, 2025

(54) WIRELESS COMMUNICATIONS USING BATCH-BASED CROSS-CODE BLOCK NETWORK CODING

(71) Applicant: Huawei Technologies Co., Ltd., Shenzhen (CN)

(72) Inventors: Yu Cao, Kanata (CA); Huazi Zhang, Hangzhou (CN); Jianglei Ma, Ottawa (CA)

(21) Appl. No.: 18/984,714

(22) Filed: Dec. 17, 2024

Related U.S. Application Data
(63) Continuation of application No. PCT/CN2022/104642, filed on Jul. 8, 2022.

(51) Int. Cl. H04W 72/1263; H04L 1/00

(52) U.S. Cl. CPC H04W 72/1263; H04L 1/0057

(57) ABSTRACT

Code blocks (CBs) are transmitted by a transmitting device and received by a receiving device in a wireless communication network. The CBs are generated based on a batch of physical layer packets to which a subset of higher-layer encoded packets are mapped, and the higher-layer encoded packets are generated from higher-layer information packets. Packets of the higher-layer information packets that are used to generate the subset of higher-layer encoded packets for the batch overlap with packets of the higher layer information packets that are used to generate a further subset of the higher-layer encoded packets for mapping to a further batch of physical layer packets. Check blocks are also transmitted and received, and each check block is generated based on portions of multiple CBs.

### CROSS-REFERENCE TO RELATED APPLICATION

This application is a continuation of International Application No. PCT/CN2022/104642, filed on Jul. 8, 2022, the disclosure of which is hereby incorporated by reference in its entirety.

### TECHNICAL FIELD

The present application relates generally to wireless communications, and more specifically to wireless communications using batch-based cross-code block network coding.

### BACKGROUND

Certain characteristics of network coding and rateless codes may be important in particular communications applications, such as extended reality (XR), vehicle-to-everything (V2X), and multi-media broadcast service (MBS), for example.

Fountain codes are an example of application-layer rateless codes, and have been used for multicast applications, such as multimedia broadcast multicast services (MBMS). One motivation for using Fountain codes in multicast applications is to reduce retransmission-related inefficiency. Automatic repeat request (ARQ)-based retransmission in multicast is inefficient because every receiver needs to send ARQ feedback, which incurs a large overhead. Furthermore, if any receiver cannot decode a multicast packet, then the transmitter needs to retransmit the packet, potentially leading to a large number of retransmissions. A Fountain code helps reduce retransmissions because the Fountain code is a rateless code. In a rateless code, each decoded packet helps decode all original information packets. However, a Fountain code also has limitations. A Fountain code is a higher-layer (application layer, for example) code, and thus has relatively higher delay in comparison to physical layer Hybrid ARQ (HARQ) schemes. Furthermore, a Fountain code is an erasure code so its performance is limited in a non-erasure channel. In addition, a Fountain code is not easy to implement in a network coding scenario because its degree distribution is optimized for a single hop, which accounts for its good performance and low decoding complexity.

Network coding schemes have been proposed for multicast, and network coding has been demonstrated to be better for multicast than traditional routing at intermediate nodes. Random linear network coding (RLNC) has been proposed as a practical implementation to realize a network coding scheme. In RLNC, source nodes transmit random linear combinations of input packets, and each intermediate node transmits random linear combinations of the packets it receives. However, RLNC may not always be practical because decoding complexity is high when the number of packets is large.

A more practical network coding scheme, called batched sparse (BATS) codes, uses a Fountain-like outer code with RLNC as an inner code. The outer code encodes original packets into batches, and RLNC is applied in each batch to produce RLNC coded packets by linearly combining different source/intermediate packets with random coefficients.

According to another approach, a cross-code block code-based HARQ scheme with different sets of subblock interleavers can function as a rateless code, which can also be used for multicast.

For multicast applications with very large files, as well as other network coding applications, each of the existing solutions referenced above has its own drawbacks. Fountain codes, RLNC, and BATS are higher-layer erasure codes, and thus each suffers from high latency as well as sub-optimal performance in non-erasure channels. Wireless communication channels are mainly non-erasure type channels, and thus the above erasure code-based solutions are not optimal or complete in realistic wireless communication channels. The cross-code block code-based HARQ scheme referenced above can function as a rateless code as noted, and although this may resolve issues associated with the above-referenced higher-layer erasure code-based solutions and have superior decoding performance, decoding complexity of a cross-code block code-based solution can be high for large file size or large number of retransmissions.

Finding a network coding approach that can resolve or at least reduce effects of one or more of the above drawbacks for multicast or multiple source cooperation-based network coding applications, for example, remains a challenge.

### SUMMARY

Some embodiments of the present disclosure relate to new batch-based cross-code block (CB) rateless coding solutions for network coding applications. For example, batch based cross-CB coding according to some embodiments uses a joint Fountain-like erasure code and cross-CB coding design to take advantage of both rateless codes and cross-CB coding. The batch design may maintain overall degree distribution of an erasure code for optimal global decoding. In addition, in mapping of higher-layer encoded packets to a batch of physical layer packets to which cross-CB coding is applied, a subblock of a CB may be used as minimum unit of decoding, which allows each batch to contribute to decoding even when all of the cross-CB coded physical layer packets are not fully decoded for a batch.

Batch-based cross-CB coding as disclosed herein may also have limited complexity because the cross-CB coding is applied on a small number of packets. Nevertheless, the batch-based cross-CB coding can still achieve much better decoding performance than a traditional network code. This is because in decoding cross-CB coded packets, a decoder can leverage soft combining, whereas a traditional network coding code is based on erasure codes, which cannot leverage soft combining because the decoder discards any packet that is not decoded successfully.

Batch-based coding may also connect different batches and provide better overall reliability and flexibility with communication link adaptation, in the sense that there is no need to guarantee that each batch is entirely decoded. This is because, if one batch is not decoded successfully, then that batch can still potentially be recovered.

Cross-CB coding may be a complete physical layer solution that can potentially compete with traditional network coding applications, but provide better support of multicast and network coding-based cooperation applications.

According to an aspect of the present disclosure, a method involves transmitting, to a receiving device in a wireless communication network, a plurality of CBs generated based on a batch of physical layer packets to which a subset of higher-layer encoded packets are mapped. The higher-layer encoded packets are generated from higher-layer information packets. Packets of the higher-layer information packets that are used to generate the subset of higher-layer encoded packets for the batch overlap with packets of the higher layer information packets that are used to generate a further subset of the higher-layer encoded packets for mapping to a further batch of physical layer packets. Such a method also involves transmitting a plurality of check blocks to the receiving device. Each check block is generated based on portions of multiple CBs of the plurality of CBS.

Another aspect of the present disclosure relates to a method that involves receiving a plurality of CBs from a transmitting device in a wireless communication network, and receiving a plurality of check blocks from the transmitting device. The CBs are generated based on a batch of physical layer packets to which a subset of higher-layer encoded packets are mapped, and the higher-layer encoded packets are generated from higher-layer information packets. Packets of the higher-layer information packets that are used to generate the subset of higher-layer encoded packets for the batch overlap with packets of the higher layer information packets that are used to generate a further subset of the higher-layer encoded packets for mapping to a further batch of physical layer packets. Each check block is generated based on portions of multiple CBs of the plurality of CBs.

An apparatus according to another aspect of the present disclosure includes a processor and a non-transitory computer readable storage medium that is coupled to the processor. The non-transitory computer readable storage medium stores programming for execution by the processor. A computer program product may be or include such a non-transitory computer readable medium storing programming.

In an embodiment, the programming includes instructions to, or to cause the processor to, transmit a plurality of CBs from a transmitting device in a wireless communication network, and transmit a plurality of check blocks from the transmitting device. In another embodiment, the programming includes instructions to, or to cause the processor to, receive the plurality of CBs from the transmitting device, and receive the plurality of check blocks from the transmitting device. The CBs are generated based on a batch of physical layer packets to which a subset of higher-layer encoded packets are mapped, and the higher-layer encoded packets are generated from higher-layer information packets. Packets of the higher-layer information packets that are used to generate the subset of higher-layer encoded packets for the batch overlap with packets of the higher layer information packets that are used to generate a further subset of the higher-layer encoded packets for mapping to a further batch of physical layer packets. Each check block is generated based on portions of multiple CBs of the plurality of CBs.

Another aspect of the present disclosure relates to a processor for an apparatus. The processor is configured to cause the apparatus to perform any of the above methods.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 illustrates batch-based cross-CB coding according to an embodiment.

FIGS. 6A and 6B depict an example of cross-CB coding in which different interleaving is performed to generate multiple sets of vertical check blocks.

FIG. 7 illustrates mapping of higher-layer encoded packets to physical layer packets for batch-based cross-CB coding according to an embodiment.

FIG. 8 illustrates a decoding example in which a subblock is a minimum decoding unit.

FIG. 9 is a signal flow diagram illustrating example communication methods according to an embodiment.

### DETAILED DESCRIPTION

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

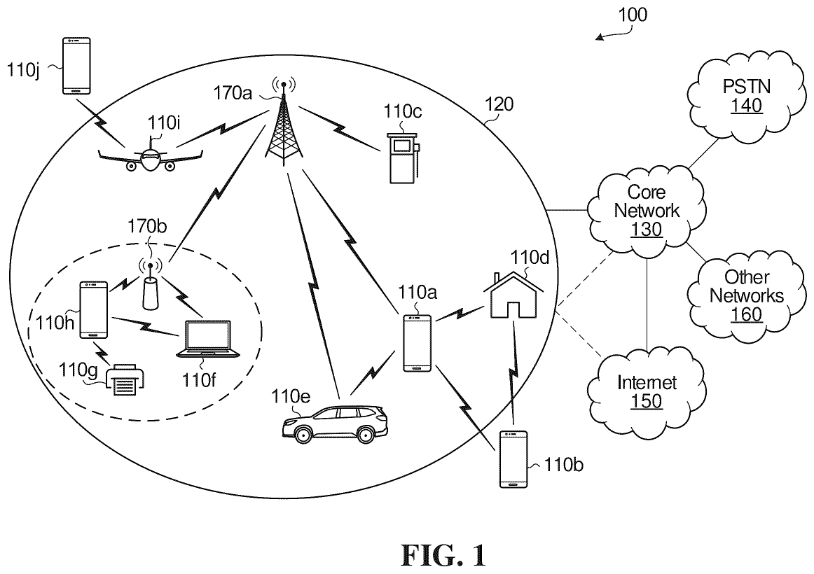

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

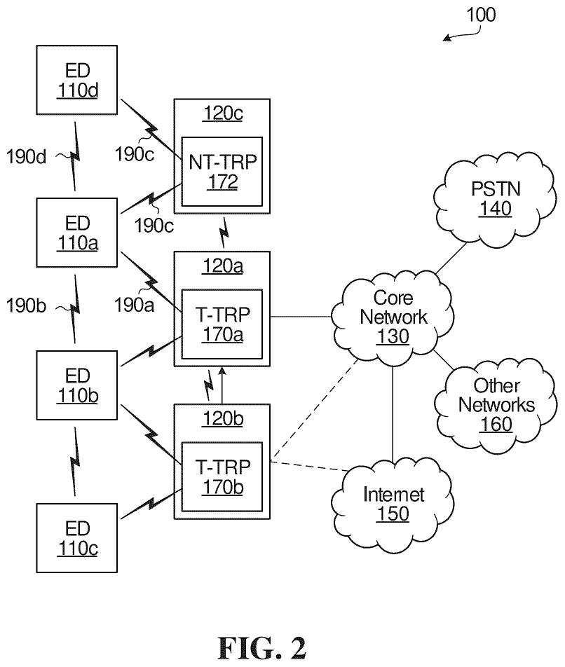

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 175 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

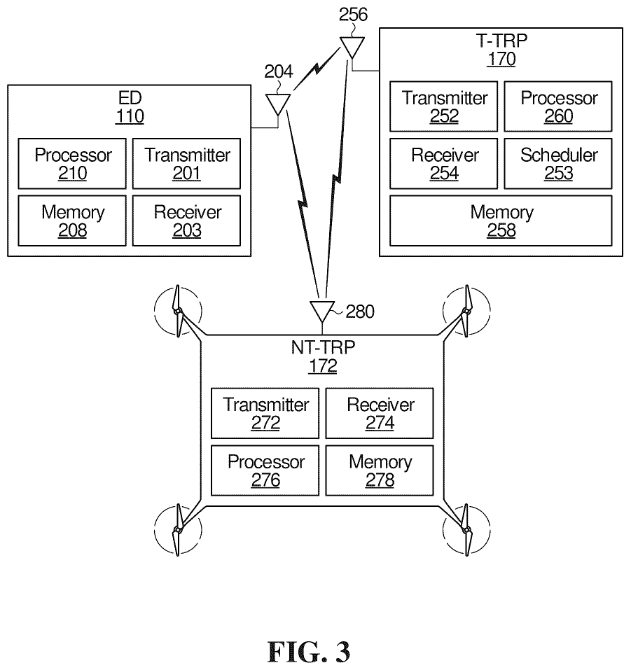

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IoT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the forgoing devices, among other possibilities. Future generation EDs 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a remote radio head, a terrestrial node, a terrestrial network device, a terrestrial base station, a base band unit (BBU), a remote radio unit (RRU), an active antenna unit (AAU), a remote radio head (RRH), a central unit (CU), a distribute unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

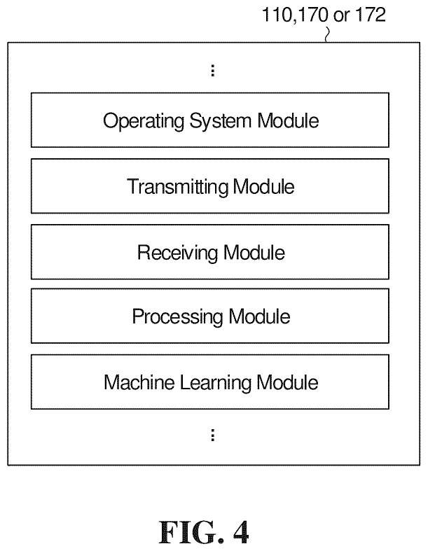

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Embodiments disclosed herein relate primarily to wireless communications using batch-based cross-code block network coding. Disclosed embodiments encompass encoding and decoding for joint cross-CB coding and higher-layer erasure coding, for example.

As discussed at least above, several existing approaches to network coding have drawbacks for multicast applications with very large files, as well as other network coding applications such as multiple source cooperation-based network coding applications. Batch-based cross-CB coding solutions as disclosed herein may be useful in addressing or at least reducing the effects of one or more of these drawbacks.

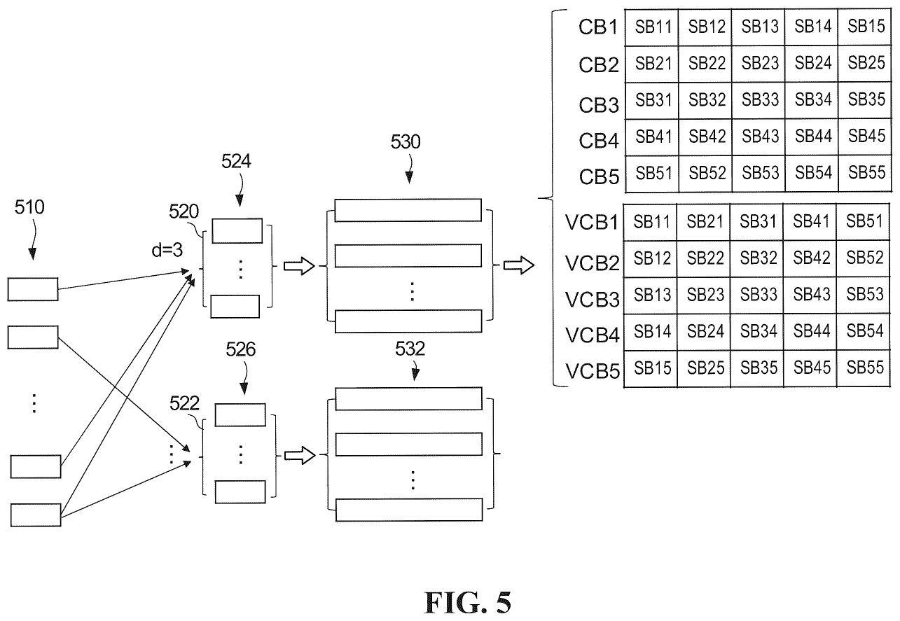

FIG. 5 illustrates batch-based cross-CB coding according to an embodiment.

A payload that is to be transmitted in a wireless communication network includes multiple information blocks, also referred to herein as information packets. The payload may first be divided into information packets at a transmitter, or may be generated or otherwise obtained as multiple information packets at a transmitter. Thus, a transmitter may, but need not necessarily, divide a payload into information packets. Information packets are illustrated at 510 in FIG. 5. Each information packet 510 may contain multiple (a number T, for example) information symbols, defined in a finite field. Individual information symbols are not illustrated in FIG. 5, in order to avoid congestion in the drawing.

Encoded packets are determined or generated based on the information packets 510 or respective different subsets of the information packets 510. Consistent with embodiments disclosed herein, information packets as shown at 510 are higher-layer information packets, associated with medium access control (MAC) layer or above, and the encoded packets are higher-layer encoded packets that are generated from the higher-layer information packets.

An erasure code or erasure coding, for example, may be used to generate higher-layer encoded packets based on the higher-layer information packets 510. In FIG. 5, batches or subsets of higher-layer encoded packets are shown at 520, 522, and other embodiments may include more than two batches or subsets. The batches or subsets 520, 522 each include a number of higher-layer encoded packets 524, 526. A code that is used to generate batches or subsets of higher-layer encoded packets from original higher-layer information packets may be referred to as a higher-layer code or an erasure code, for example.

As an example, consider an embodiment in which a code design that encodes a number K of original higher-layer information packets 510 into batches 520, 522 of higher-layer encoded packets. Generation of higher-layer encoded packets, as a whole, includes all higher-layer information packets 510. For example, a code such as a Reed Solomon (RS) code may be applied to all of the higher-layer information packets 510 to generate higher-layer encoded packets, and the batches or subsets 520, 522 each include a number of those higher-layer encoded packets, which may be randomly, sequentially or otherwise selected from the full set of higher-layer encoded packets. In other embodiments, each individual batch or subset 520, 522 of higher-layer encoded packets is based on a subset of fewer than all of the higher-layer information packets 510, and the respective batches or subsets of higher-layer information packets for generating different batches or subsets 520, 522 of higher-layer encoded packets are different. In either case, whether higher-layer encoded packets are generated based on all of the higher-layer information packets and those higher-layer encoded packets are distributed amongst or between subsets or batches of higher-layer encoded packets, or respective different subsets of higher-layer information packets are used to generate different batches or subsets of higher-layer encoded packets, there is overlap between higher-layer information packets that are used to generate the batches or subsets of higher-layer encoded packets.

Regarding this overlap between higher-layer information packets that are used to generate batches or subsets of higher-layer encoded packets, in the case of generating the higher-layer encoded packets based on all of the higher-layer information packets and then distributing the higher-layer encoded packets between batches or subsets, there may be full overlap between original information packet subsets, in the sense that all of the higher-layer encoded packets are generated based on all of the original higher-layer information packets. In embodiments in which subsets of higher-layer encoded packets are generated based on different subsets of original higher-layer information packets, there are common higher-layer information packets that are part of multiple subsets, as illustrated by the multiple arrows from the higher-layer information packet 510 at the bottom in the example shown in FIG. 5, but preferably no subsets of higher-layer information packets are entirely identical. Again, in both of these cases of generating subsets of higher-layer encoded packets based on all higher-layer information packets or based on respective different subsets of higher-layer information packets, there is overlap between the higher-layer information packets that are used to generate different subsets of higher-layer encoded packets.

Consider now an example of generating batches or subsets 520, 522 of higher-layer encoded packets based on respective subsets of higher-layer information packets 510. The number of higher-layer information packets 510 in a subset upon which a batch or subset 520, 522 of higher-layer encoded packets is based may also or instead be referred to as a degree d for each batch. In the example shown in FIG. 5, d=3 for batch or subset 520. This is illustrated in FIG. 5 by the 3 arrows from 3 of the higher-layer information packets 510 toward 520. This is an example only, and a different degree may also or instead be used in other embodiments. Different subsets of higher-layer information packets may include different numbers of higher-layer information packets, such that d can be different (e.g., d₁, d₂, . . . ) for different batches or subsets. In the example shown in FIG. 5, the degree for batch 522 may be different from the degree 3 used for batch 520. Degree (s) d for each batch may be selected by sampling a degree distribution, such as robust soliton distribution (RSD) that is used in Luby transform (LT) codes for example. A degree distribution characterizes the probability distribution of a random variable according to which the degree is generated. Each sample of the degree distribution can be different from others, and therefore the degree d for different batches is also different. The above examples of generating the degree d are intended to be non-limiting and illustrative, and a different way of generating the degree may also or instead be used in other embodiments.

Details regarding LT codes can be found in Michael Luby, “LT Codes”, Proceedings of the 43rd Annual IEEE Symposium on Foundations of Computer Science, 2002, FOCS′02, pp 271-282 (“Luby”). RSD as referenced above is one example of a degree distribution, and appears as Definition 11 in Luby. Another example of a degree distribution is ideal soliton distribution, consistent with Definition 9 in Luby. RSD may be advantageous as a degree distribution to provide high decoding probability, with many information packets in low degrees so the decoding can start and keep going, and sufficient high degrees such that all information packets are covered. Another potential advantage of RSD is that decoding complexity, which is proportional to the number of edges in the decoding graph, is low.

These potential advantages of RSD are illustrative of how a degree distribution from which degree(s) d may be selected may be optimized or designed for effective and low complexity decoding. Selection from a degree distribution is one example of how a degree for higher-layer information packet encoding may be obtained.

After d is obtained for a batch, d higher-layer information packets are selected, randomly or according to another selection criterion, from the original K higher-layer information packets. The d selected higher-layer information packets are then processed, through a linear pre-coding stage, for example, to generate each batch or subset 520, 522 of higher-layer encoded packets in the example shown.

According to one illustrative embodiment, a batch or subset of N higher-layer encoded packets is generated as a linear combination, in the respective finite field, of the d higher-layer information packets that are selected for generating that batch or subset of higher-layer encoded packets. This may be expressed as X=(S₁, S₂, . . . , S_{d}) G, where: each of S₁, S₂, . . . , S_{d} is a dimension T×1 vector representing the T symbols in higher-layer information packet 1, 2, . . . d, respectively; and G is a generator matrix with dimension d×N containing linear coefficients for producing the higher-layer encoded packets of the batch or subset of higher-layer encoded packets. Each column of G represents a linear coefficient that is used to produce a corresponding higher-layer encoded packet in the batch or subset in this example. X=(X₁, X₂, . . . , X_{N}), X is dimension T×N, and Xᵢ represents an i-th higher-layer encoded packet and is a dimension T×1 vector with each element representing one of the T symbols of the i-th higher-layer encoded packet.

Put another way, an output of N higher-layer encoded packets is X, which has dimension T×N. In X, each column vector represents one higher-layer encoded packet containing T symbols. Each linear combination coefficient can be a pseudorandom linear coefficient or another systematic design, for example. This type of code becomes an LT code under the following conditions: N=1, d is selected by sampling RSD, and the linear combination is an exclusive-OR (XOR) operation.

The N higher-layer encoded packets form a batch or subset that is to be processed using cross-CB coding. Cross-CB coding may also or instead be referred to as cross-CB code-based coding, physical layer coding for transmission and retransmission, or two-dimensional (2D) coding, for example. In order to enable a receiver to decode a batch or subset of higher-layer encoded packets that were generated based on a linear combination of higher-layer information packets, for example, the linear coefficients used to generate the higher-layer encoded packets of the batch or subset are provided to or the receiver. One way to provide the linear coefficients to the receiver is to include an indication of each of the linear coefficients, and/or an index of information packets, that are used to generate the higher-layer encoded packet into a packet header. More generally, information indicative of how each batch or subset of higher-layer encoded packets was generated may be transmitted with the batch or subset as in this example, or separately in control signaling for example. The information indicative of how each batch or subset of higher-layer encoded packets was generated may include one of, or a combination of, any of the following: which d higher layer information packets are used to generate the batch or subset of higher-layer encoded packets, and the linear coefficients used to combine the d information packets. Note the packet header for the higher-layer encoded packet may be included as part of the payload along with the encoded bits of the higher-layer encoded packet, to be mapped to physical layer (PHY) packets as disclosed herein.

In order to use cross-CB coding on each batch or subset of higher-layer encoded packets, the N higher-layer encoded packets of each batch or subset are mapped to M physical layer (PHY) packets. Then, cross-CB coding can be applied to the M PHY packets. Each PHY packet includes content that is to be transmitted, and that content may be referred to as data, information, or a payload, for example. A PHY packet may include information bits of a transport block (TB), for example, and as described in 5G NR or 4G LTE standards, a TB may be segmented into one or multiple code blocks (CBs) for transmission. It can be seen that at least in this sense, mapping a batch or subset of higher-layer encoded packets to a batch of PHY packets as disclosed herein may be considered to be equivalent to mapping the batch or subset of higher-layer encoded packets to one or more TBs or to information bits of one or more TBs. Put another way, mapping a batch or subset of higher-layer encoded packets to a batch of PHY packets may be considered to be equivalent to mapping the batch or subset of higher-layer encoded packets to one or more CBs or to information bits (also known as input bits) of one or more CBs. A batch or subset of PHY packets may also or instead be considered as including information bits or input bits of one or more TBs and/or CBs. Similarly, a TB may be considered as including information bits of (or from) one or more PHY packets, and a CB may be considered as including information bits or input bits of (or from) one or more PHY packets.

A TB may have an overall cyclic redundancy check (CRC) and associated parity bits, and each code block may have its own CRC. In the case when there is only 1 CB for a TB, only 1 CRC is needed as the CRC works for both the CB and TB. More details regarding TBs, CBs, and PHY packets are provided elsewhere herein, at least below.

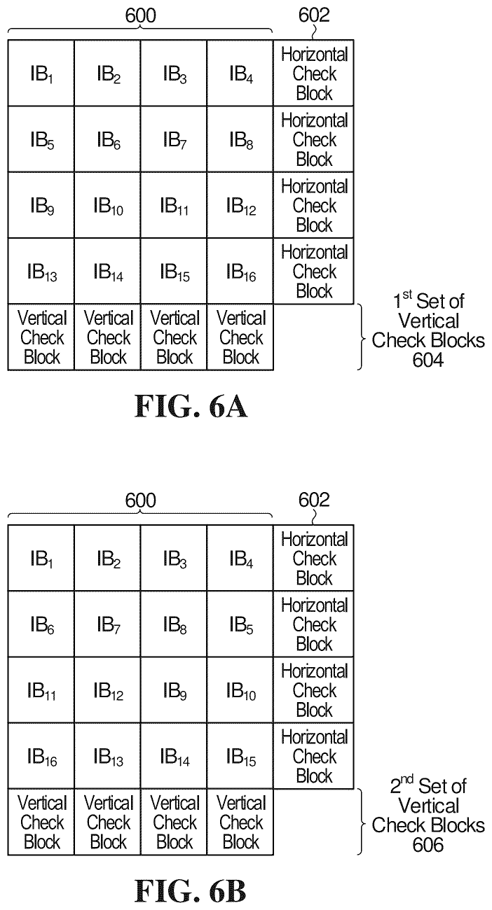

Before considering batch-based cross-CB coding in FIG. 5, reference is made to FIGS. 6A and 6B, which depict an example of cross-CB coding in which different interleaving is performed to generate multiple sets of vertical check blocks. FIG. 6A shows a transport block 600, with the input bits divided into sets of input bits IB₁, IB₂, . . . , IB₁₆. Horizontal check blocks 602 are determined based on rows within the transport block, and vertical check blocks 604 are determined based columns of sets of encoder input bits. Overall cross-CB coding in FIG. 6A is based on the input bits (IBs), which are logically arranged in rows (four rows in the example shown) and columns (four rows in the example shown). Each horizontal check block 602 is determined based on the IBs in a row, and may be generated by encoding the IBs in a row using a code that may be referred to as a horizontal code for example. Similarly, each vertical check block 604 is determined based on the IBs in a column, and may be generated by encoding the IBs in a column using a code that may be referred to as a vertical code for example. Cross-CB coding is also described in further detail below, with illustrative examples of codes that may be used to generate horizontal and vertical check blocks.

A TB may be segmented into one or multiple CBs. For example, in FIG. 6A, each row of IBs may be information bits or input bits of a respective CB, in which case there would be four CBs in the TB 600 in FIG. 6A. The IBs of a TB or CB may be from one or more PHY packets to which higher-layer encoded packets are mapped as described herein. The horizontal check blocks 602 are generated for transmission of the CBs. Transmission of CBs involves transmitting information bits or input bits of the CBs and check blocks, referenced herein as horizontal check blocks, for the CBs. PHY packets as referenced herein include information bits for CBs, but not the check blocks. An initial transmission of CBs may include both information bits (input bits) of the CBs, and the horizontal check blocks 602. In at least this sense, transmitting CBs may involve transmitting both information bits (input bits) and check blocks, generated based on a batch of PHY layer packets. Vertical check blocks 604 may be generated based on IBs of different CBs, for a retransmission that may but need not necessarily also include IBs. A retransmission may include only check blocks, without IBs.

FIG. 6B shows the input bits after interleaving. In this example, interleaving is performed as between blocks of input bits in the rows. It can be seen that in the first row, the order of the blocks is not changed, but in the second, third and fourth rows, the order is changed. A new set of vertical check blocks 606 is determined based on the reordered encoder input bits. Initially, horizontal CBs including the input bits, and the horizontal check blocks 602, are transmitted. Then, vertical check blocks from the first set 604 are transmitted if necessary. Then, vertical check blocks from the second set 606 are transmitted if necessary. Further sets of vertical check blocks may be generated and transmitted, based on further interleaving, if at least one horizontal CB still fails to be decoded successfully.

With the example of FIGS. 6A and 6B, the interleaving is performed at the subblock (IBx) level. However, other types of interleaving such as bit-wise interleaving may also or instead be used in vertical check block generation for cross-CB coding. More generally, the sets of bits for use in determining one set of vertical check blocks are organized differently than the sets of bits for use in determining another set of vertical check blocks. Subblock-level interleaving and bit-wise interleaving are two specific examples of different organization of bits for vertical check block generation.

This example is illustrative of cross-CB coding, in that the vertical check blocks 604, 606 are generated based on portions, in particular subblocks in this example, of multiple CBs. In this sense, the coding “crosses” CBs. Cross-CB coding may also or instead be referred to as two-dimensional (2D) coding, in horizontal and vertical dimensions for example, in FIGS. 6A and 6B.

The example of cross-CB coding in FIGS. 6A and 6B is intended solely for illustrative purposes. Cross-CB coding for batches of PHY packets as disclosed herein is not in any way limited to this particular example. International application PCT/CN2021/121483, filed on Sep. 28, 2021, and entitled “METHODS AND APPRATUSES FOR WIRELESS COMMUNICATION RETRANSMISSION USING CHECK BLOCKS GENERATED ACCORDING TO SUBBLOCK INTERLEAVERS”, for example, provides additional examples of different subblock interleavers for retransmissions. Another possible variation from the specific example in FIGS. 6A and 6B involves extending cross-CB coding to cross multiple packets, as in United States Patent Application Publication US 2021/0297180 A1, published on Sep. 23, 2021, and entitled “METHODS AND SYSTEMS FOR NETWORK CODING USING CROSS-PACKET CHECK BLOCKS”, for example. In the example shown in FIGS. 6A and 6B the IBs are shown as being part of a single TB 600, but this is not necessarily the case in all embodiments.

Other variations in cross-CB coding are also possible.

Returning now to FIG. 5, vertical check blocks (VCBs) are illustrated somewhat differently than in FIGS. 6A and 6B, and horizontal check blocks are not shown separately in FIG. 5 in order to avoid congestion in the drawing. The example shown includes, a total of 5 CBs for one batch 530 of PHY layer packets. The CBs may correspond to 1 or multiple PHY packets or TBs in the batch. For example, if each PHY packet contains only 1 CB, then the 5 CBs correspond to M=5 PHY packets for batch 530. In another example, there are M=1 PHY packet in batch 530, and the TB that corresponds to the PHY packet is divided or segmented into 5 CBs (CB1 to CB5). Each CB includes multiple subblocks (five in this example). The CBs in FIG. 5 correspond to PHY packets 530 in a first batch of PHY packets, and check blocks for the CBs are generated by applying a forward error correction (FEC) code to information bits or input bits of the CBs for example. These check blocks are also referred to at least above as horizontal check blocks generated using a horizontal code. Cross-CB coding is applied by selecting a subblock, or more generally a portion of data (information bits or input bits), from each of the one or multiple CBs for the M packets in a batch of PHY packets, and applying a FEC code (or a channel code) to generate a VCB. A FEC code for cross-CB coding may also or instead be referred to as a vertical code.

A FEC code that is used for generating a VCB may be independent of a physical layer FEC code, referred as a horizontal code, that is used for encoding CBs for an initial transmission before a VCB is transmitted. Thus, the two FEC codes (horizontal and vertical) can be the same code or same type of code, or different codes or types of codes. For example, both FEC codes may be low density parity check (LDPC) codes, or one FEC code may be an LDPC code and the other FEC code may be a Turbo code. Furthermore, the code rates of the two FEC codes may be the same or different.

In some embodiments, CBs with horizontal check codes are transmitted in an initial transmission, and VCBs may subsequently be sent as a retransmission in a HARQ scheme or other incremental redundancy approach that may involve multiple transmissions if an initial transmission is not correctly received and decoded, for example. Furthermore, by using interleaving such as subblock-level interleaving and/or bit-wise interleaving as described by way of example herein, multiple sets of VCBs can be generated. For example, each PHY packet among the M PHY packets 530 in FIG. 5 may contain information bits or input bits of one CB, and each CB may include five subblocks. One set of five VCBs is generated in FIG. 5, based on the subblocks shown. For example, VCB1 is generated based on SB11, SB21, SB31, SB41, and SB51; VCB2 is generated based on SB12, SB22, SB32, SB42, and SB52; and so on. This representation of VCBs in FIG. 5 is not intended to indicate that the SBs are transmitted with a VCB, but rather to indicate the SBs that are used in generating each VCB. As described herein, CBs that include SBs (and a horizontal check block for each CB, not shown in FIG. 5) may be transmitted in an initial transmission, and subsequent retransmissions may include VCBs. Information bits of CBs or SBs may or may not also be included with VCBs in a retransmission.

In implementing a cross-CB coding approach consistent with FIG. 5, a transmitter may send at total of ten transmissions and retransmissions for each batch, with each transmission or retransmission containing one CB (CB1, CB2, . . . , CB5), or one VCB (VCB1, VCB2, . . . , VCB5). As an example, suppose that each PHY packet 530 in the batch contains information bits or input bits of one CB, each CB includes P subblocks, and Q sets of subblock interleavers are used, where each sets of subblock interleavers generates P VCBs. Further suppose that each transmission contains 1 VCB or 1 CB and each VCB uses a similar amount of time frequency resource as the original CB). In this scenario, then M+Q*P transmissions/retransmissions can be sent using cross-CB coding for transmission and retransmission for each batch of PHY packets. In some other scenarios, each retransmission may contain more than 1 VCB, the number of VCBs and code rate used for each retransmission may vary and may depend on how retransmissions are scheduled in a network, for example.

In FIG. 5, the example shown illustrates one possible combination of subblocks for VCB generation, and subblock interleaving may be used to generate VCBs from different combinations of subblocks, for other retransmissions for example. Examples of using a design of different subblock interleavers as well as methods to use different subsets of subblock interleavers, can be found in more detail in International application PCT/CN2021/121483 referenced above.

In FIG. 5, five CBs and five VCBs are illustrated as an example. The number of CBs and/or the number of VCBs may be different in different embodiments, and the number of CBs and VCBs may or may not be the same.

An important feature in batch-based cross-CB network coding is to map higher-layer encoded packets to PHY packets, which as described above is equivalent to mapping those higher-layer encoded packets to one or more TBs, one or more CBs, or to information bits or input bits of one or more TBs and/or one or more CBs. There are different ways to implement such mapping, and illustrative examples include the following: each higher-layer encoded packet is mapped to a PHY packet that includes information bits of one TB (M=N), which in effect maps the encoded packet to a TB or specifically to the information bits of a TB; each higher-layer encoded packet is mapped to a PHY packet or part of a PHY packet that includes information bits or input bits of one CB, which in effect maps the encoded packet to a CB or specifically to the information bits or input bits of a CB; or each higher-layer encoded packet is mapped to a PHY packet or part of a PHY packet that includes information bits or input bits of one subblock (N=M*P if one packet contains one CB), which in effect maps the encoded packet to a subblock. Mapping selection may depend on one or more factors or criteria, such as any one or more of: size of the higher-layer encoded packets, maximum code block size, and how higher-layer encoded packets are to be decoded if one or more higher-layer encoded packets or part of a batch were not decoded successfully. If a higher-layer encoded packet is mapped to a TB, a CB, or a subblock, then the TB, the CB, or the subblock, respectively, becomes the minimum unit that can be decoded.

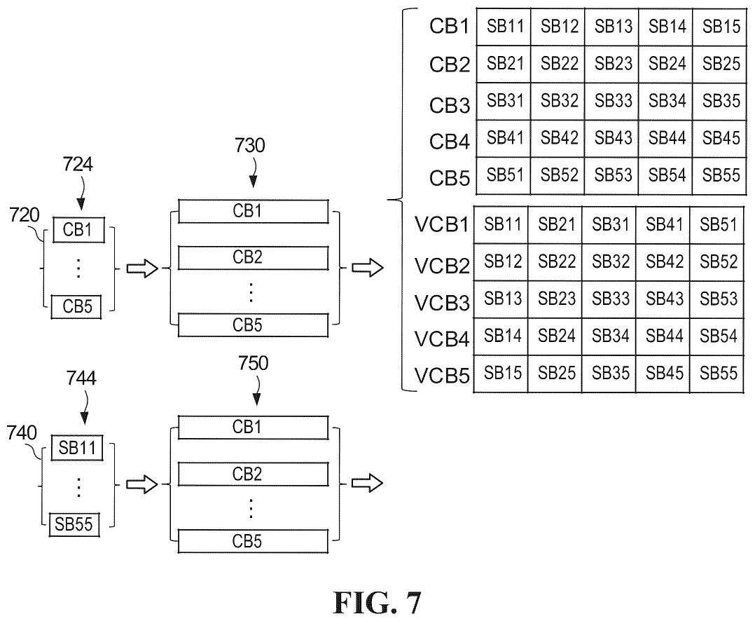

FIG. 7 illustrates mapping of higher-layer encoded packets to physical layer packets for batch-based cross-CB coding according to an embodiment. FIG. 7 includes two examples, for CB-based mapping (N=M=5) of a batch or subset 720 of five higher-layer encoded packets 724 to PHY packets 730, and subblock-based mapping (N=25, M=5) of a batch or subset 740 of twenty five higher-layer encoded packets 744 to PHY packets 750. In both examples, each of the M PHY packets 730, 750 includes information bits of one CB. However, in another embodiment each PHY packet may include information bits of multiple CBs, and each encoded packet may map to one TB as well.

For example, there may be N=5 higher-layer encoded packets in one batch or subset that is to be mapped to PHY packets in the same batch, each higher-layer encoded packet may be mapped to a PHY packet, and each PHY packet may correspond to (i.e., including information bits of) one TB (N=M=5). Each TB may be segmented into two CBs, as an example. In this case, cross-CB coding may be used to implement or support a type of incremental redundancy or retransmission for each batch, and may be applied to the total of ten CBs (two CBs from the five TBs), with each CB including ten subblocks to produce another ten VCBs. Supposing that each TB, which contains two CBs in this example, can be sent in one transmission and that two VCBs are sent in 1 retransmission, then a total of 10 transmissions and retransmissions can be used to send the ten CBs and ten VCBs for the batch. This example results in a total of one hundred subblocks for each batch.

In another example, suppose that there are again M=5 PHY packets, each PHY packet corresponds to one TB and each TB consists of two CBs. However, for this example suppose that each of the higher-layer encoded packets corresponds to (i.e., includes information bits or input bits of) one CB. In this case, there are N=10 higher-layer encoded packets mapped to the batch of 5 PHY packets. Batch-based cross-CB coding as disclosed herein is flexible and can support any of various mappings of subblocks, code blocks, transport blocks, higher-layer encoded packets, and PHY packets, as illustrated by the foregoing examples. The examples herein are not exhaustive. Not all possible combinations are provided as examples.

One possible advantage of mapping one higher-layer encoded packet to one subblock is to enable the subblock size to be the minimum decoding unit. When subblock size is the minimum decoding unit, the following scenario is possible:
when the receiver cannot fully decode the entirety of one batch using the cross-CB code-based inner code, the receiver can still recover some subblocks (or put another way, the receiver can recover some higher-layer encoded packets);
even with multiple retransmissions of VCBs that are based on different subblock interleavers, the subblock remains the minimum decoding unit;
recovered subblocks map to higher-layer encoded packets, and therefore recovered higher-layer encoded packets may help in decoding the “global” higher-layer code.

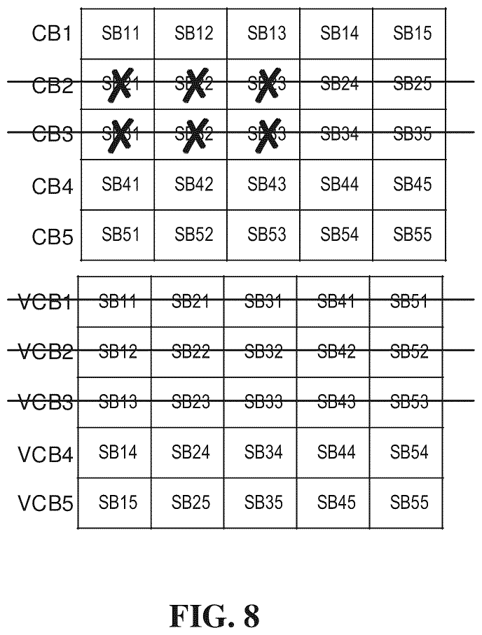

FIG. 8 illustrates a decoding example in which a subblock is a minimum decoding unit. In the example shown, even though two CBs (CB2, CB3) and three VCBs (VCB1, VCB2, VCB3) are not successfully decoded, as indicated by the horizontal lines through several CBs and VCBs, only the six subblocks indicated by the “X” symbols in the drawing are not decodable. Instead of discarding two entire CBs in this example, parts of those CBs are recovered. For example, SB24 is not decoded in CB2 but is recovered from VCB4. Similarly, SB25 is not decoded in CB2 and SB34 and SB35 are note decoded in CB3, but SB25 is recovered from VCB5, SB34 is recovered from VCB4, and SB35 is recovered from VCB5.

Decoding of batch-based cross-CB codes involves: local batch-based cross-CB joint decoding, which may also or instead be referred as two-dimensional (2D) joint decoding; and global higher-layer code decoding.

In batch-based cross-CB joint decoding, decoding information such as soft information can be exchanged between CBs and VCBs to help improve decoding performance. After such cross-CB joint decoding, even if some CBs cannot be recovered, hard decisions of correctly decoded CBs can be mapped back to the higher-layer encoded packets to help to decode the original higher-layer information packets. In the case when the mapping is subblock based, hard decisions of decoded subblocks in the decoded CB/VCBs can be mapped back to the higher-layer encoded packet sent for global higher-layer code decoding instead of being discarded. In the example shown in FIG. 8, although five out of ten CBs are not decoded successfully, because they do not pass a cyclic redundancy check for example, only six out of twenty five subblocks are not recovered.

Global higher-layer code decoding is performed to recover original information packets. If a batch of PHY packets is fully recovered by cross-CB joint decoding, then all of the corresponding higher-layer encoded packets are recovered. However, if cross-CB joint decoding cannot fully decode a batch of PHY packets, then the partial decoding output of all the recovered subblocks/TB/CBs from each batch may be translated into higher-layer encoded packets and passed through higher-layer code decoding to decode the original information packets.

Higher-layer code decoding may also or instead involve belief propagation (BP) decoding. If the generator matrix of a batch of higher-layer encoded packets is full rank, then the d information packets can be decoded and eliminated from remaining undecoded batches. After decoding batches, a degree 1 check node (coded packets) is first found and eliminated from all remaining undecoded variable nodes (information packets). The process continues until no more degree 1 check nodes can be found or all variable nodes (information packets) are successfully decoded.

Inactivation decoding is another possible option for decoding a higher-layer code. For example, if BP decoding cannot fully recover all original information packets, then inactivation decoding can be further performed. BP decoding and inactivation decoding are example methods of decoding the higher-layer code; there may be other methods or techniques that can be used to decode a higher-layer code depending on a decoding complexity requirement, for example.

A potential advantage of maintaining degree distribution as disclosed herein is that each batch of higher-layer encoded information packets is protected nearly equally by the cross-CB coding, and each batch is generated based on an original optimized degree distribution that provides good decoding performance and low decoding complexity. Thus, higher-layer coding and cross-CB coding, in combination, can also provide optimal decoding performance of BP decoding and low decoding complexity.

Embodiments disclosed herein encompass various aspects of batch-based cross-CB coding, which may include either or both of encoding and decoding.

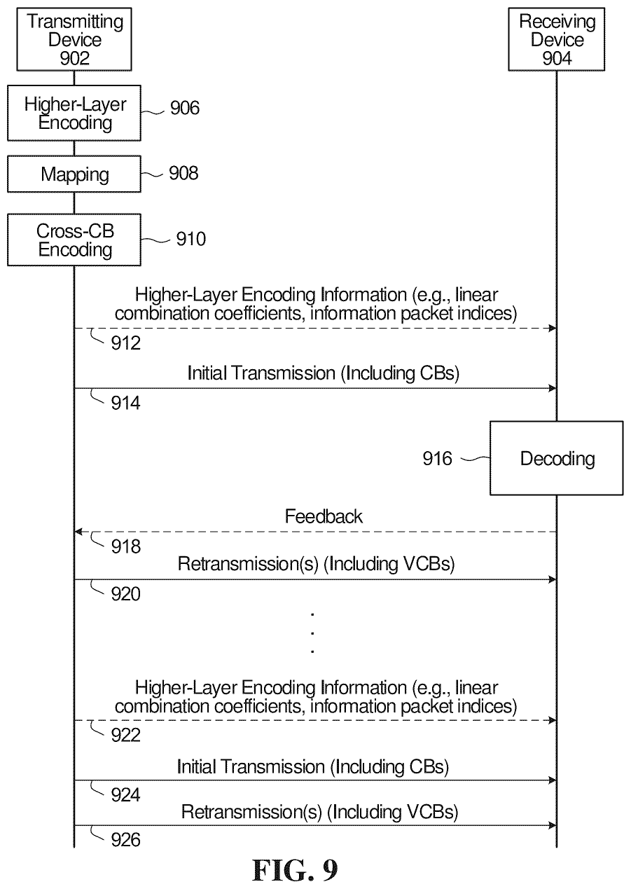

For example, methods consistent with the present disclosure include methods related to transmitting, receiving, or both. FIG. 9 is a signal flow diagram illustrating example communication methods according to an embodiment, and includes both transmit-side and receive-side operations.

A method may involve, at a transmit side or a transmitting device 902 in a wireless communication network, higher-layer encoding of higher-layer information packets at 906, to generate higher-layer encoded packets. As discussed in detail elsewhere herein, batches or subsets of the higher-layer encoded packets are mapped to batches of PHY packets, and the mapping at 908 represents such mapping of higher-layer encoded packets to a batch of PHY packets. CBs are based on the PHY layer packets, and cross-CB encoding applied to CBs is shown at 910. Transmitting the CBs to a receiving device 904 in the wireless communication network is shown at 914 as an initial transmission including the CBs. A counterpart receive-side operation, at the receiving device 904, for example, involves receiving the CBs from the transmitting device 902.

The information bits of the CBs come from a batch of physical layer packets, to which a batch or subset of higher-layer encoded packets are mapped. Each CB may be encoded by a horizontal code, such as an LDPC code, at 910 before transmitting to the receiving device as described earlier. In the context of transmitting CBs, reference is made herein to transmitting CBs that are generated based on a batch of physical layer packets. Information bits of a CB that is transmitted by a transmitting device and received by a receiving device are from one or more physical layer packets. In addition, a transmission as shown at 914 includes the information bits of the CBs and corresponding check blocks generated by encoding the information bits using a horizontal code. This is illustrative of how, in the context of transmitting CBs, the CBs may be considered as having been generated based on a batch of physical later packets.

The higher-layer encoded packets, which are mapped to the batch of physical layer packets, are generated from higher-layer information packets. Higher-layer information packets that are used to generate the batch or subset of higher-layer encoded packets for one batch of physical layer packets overlap with packets of the higher layer information packets that are used to generate a further batch or subset of the higher-layer encoded packets for mapping to a further batch of physical layer packets.

At 920, FIG. 9 illustrates transmitting a plurality of check blocks, by the transmitting device 902 to the receiving device 904. The check blocks are shown by way of example as VCBs included in one or more retransmission. A counterpart receive-side operation at 920 involves receiving, by the receiving device 904 from the transmitting device 902, the plurality of check blocks. Each check block is generated as disclosed herein, based on portions of multiple CBs of the plurality of CBs. Although cross-CB encoding is shown in FIG. 9 at 910, encoding to generate a check block for an initial transmission of each CB and encoding to generate cross-CB check blocks may be performed separately.

In some embodiments, an initial transmission of CBs includes information bits or input bits of the CBs and respective check blocks for CBs, and the check block for each CB is generated based on a first code (also referenced herein as a horizontal code), such as a FEC code, applied to information bits of the CB, which are also in a batch of physical layer packets. Other check blocks such as VCBs are generated based on a second code (also referenced herein as a vertical code), which may also be a FEC code for example, applied to portions of multiple CBs. Check blocks for CBs, and other check blocks such as VCBs, may be generated together at 910, or VCBs may be generated separately as needed for one or more retransmissions. Horizontal and vertical coding are not shown separately in FIG. 9 in order to avoid further congestion in the drawing.

Other operations are also illustrated in FIG. 9. For example, a method may involve transmitting further CBs at 924, by the transmitting device 902 to the receiving device 904, and/or receiving the further CBs at 924, by the receiving device from the transmitting device. The further CBs are generated based on the further batch of physical layer packets referenced above. Transmitting further check blocks by the transmitting device 902 to the receiving device 904, and receiving such further check blocks by the receiving device from the transmitting device, are shown at 926. Each further check block is generated based on portions of multiple CBs of the further CBs. As an example, the CBs and the VCBs at 914, 920 may be associated with a first batch of PHY packets, and the further CBs and further VCBs at 924, 926 may be associated with a next batch of PHY packets after all transmissions and any retransmissions for the first batch of PHY packets have been completed or the first batch of PHY packets has been correctly received and decoded.

The higher-layer encoded packets that are mapped to physical layer packets may have been generated during higher-layer encoding at 906 in any of a number of ways. For example, the higher-layer encoded packets may have been generated based on a higher-layer erasure code applied to the higher-layer information packets. This is also described at least above in the context of generating higher-layer encoded packets based on all of the higher-layer information packets, in which case there is full overlap between higher-layer information packets that are used to generate the subsets of higher-layer encoded packets.

In another embodiment, packets of the higher-layer information packets that are used to generate the subset of higher-layer encoded packets include a subset that includes fewer than all of the higher-layer information packets, and the packets of the higher-layer information packets that are used to generate the further subset of higher-layer encoded packets include a further subset that also includes fewer than all of the higher-layer information packets. The subset and the further subset of the higher-layer information packets, from which the subset and the further subset of the higher-layer encoded information packets are generated, are different from and overlapping with each other.

According to an embodiment, the subset of the higher-layer information packets includes a first number d₁ of the higher-layer information packets and the further subset of the higher-layer information packets includes a second number d₂ of the higher-layer information packets. d₁ and d₂ may be sampled from a degree distribution. The d₁ and d₂ higher-layer information packets in the subset and the further subset of the higher-layer information packets are selected, randomly in some embodiments, from the higher-layer information packets.

The subset of the higher-layer encoded packets may have been generated at 906 based on linear combinations of the subset of the higher-layer information packets, in which case a method may include transmitting coefficients for the linear combinations by the transmitting device 902 to the receiving device 904 and/or receiving the coefficients by the receiving device from the transmitting device. This is shown in FIG. 9 at 912. Higher-layer encoding information that is transmitted by the transmitting device 902 and received by the receiving device 904 may include these coefficients, indices or other identifiers or indicators of higher-layer information packets that are combined to generate higher-layer encoded packets, and/or other information associated with higher-layer encoding or decoding. Higher-layer encoding information may be transmitted with CBs, or separately as shown. In some embodiments, the higher-layer encoding information shown at 912 is included as part of the packet header of the corresponding higher-layer encoded packet. The packet header may be included as the payload of higher-layer encoded packets that are mapped to PHY packets, which are further transmitted after cross-CB encoding. In this scenario, no separate signaling is needed to transmit the higher-layer encoded information. This also applies to the higher-layer encoded information at 922 for a further batch.

Mapping options that may be applied at 908 include TB, CB, and subblock mapping. In particular, each higher-layer encoded packet in a batch may map to one physical layer packet based on which a TB that includes one or more CBs is generated, each higher-layer encoded packet in a batch may map to a physical layer packet (or a part of a physical layer packet) based on which one CB is generated, or each higher-layer encoded packet may map to a physical layer packet (or a part of a physical layer packet) based on which one of the portions of a CB is generated.

Regarding portions of a CB, this refers to cross-CB coding and portions of different CBs that are used in generating a check block. For example, each CB may include subblocks, each of the higher-layer encoded packets may map to one of the physical layer packets (or a part of a physical layer packet) based on which one of the subblocks is generated, and the portions of multiple CBs based which each check block is generated may be or include a subblock of each of the multiple CBS.

Much of the present disclosure focuses primarily on generation and transmission, or reception of CBs and check blocks. In terms of application to communications, CBs may be transmitted and/or received as an initial transmission in an incremental redundancy retransmission or HARQ process for example. With reference to FIG. 9, for example, the transmission or reception of CBs at 914 may be associated with an initial transmission for a batch of physical layer packets. A method may also involve transmitting by the transmitting device 902 to the receiving device 904 and/or receiving by the receiving device from the transmitting device, multiple sets of check blocks generated based on different combinations of portions of CBs. Transmission and reception of one set of check blocks is shown by way of example at 920, and the symbols below 920 in FIG. 9 are intended to represent possible further transmissions of additional sets of check blocks, in subsequent retransmissions for a batch for example.

Transmitting or receiving multiple sets of check blocks may involve transmitting (or receiving) a respective one of the multiple sets of check blocks based on receiving (or transmitting) at 918 for example, negative feedback. Decoding may be attempted at 916 by the receiving device 904, and negative feedback for one or more physical layer packets of a batch may be transmitted by the receiving device and received by the transmitting device 902 if decoding is not successful. Negative feedback is not limited to explicit signaling of feedback. Absence of positive feedback at 918 within a certain time of transmission of the CBs at 914, for example, may be another form of negative feedback. There may be one or more feedback/retransmission cycles at 918, 920.

Retransmissions may be stopped and a transmitting device and receiving device may switch to another batch of physical layer packets and CBs after positive feedback for all of the physical layer packets of a current batch. A transmit-side operation may involve transmitting, by the transmitting device 902 to the receiving device 904 based on receiving positive feedback from the receiving device, code blocks generated from a further batch of physical layer packets. A counterpart receive-side operation involves receiving, by the receiving device 904 from the transmitting device 902 based on transmitting positive feedback by the receiving device, code blocks generated from the further batch of physical layer packets.

Positive feedback is not the only mechanism that may trigger an end of retransmissions. For example, a method may involve transmitting, by the transmitting device 902 to the receiving device 904 based on a maximum number of transmissions of sets of check blocks, code blocks generated from the further batch of physical layer packets. Similarly, a receive method may involve receiving, by the receiving device 904 from the transmitting device 902 based on a maximum number of transmissions of sets of check blocks, code blocks generated from the further batch of physical layer packets.

Transmitting and receiving code blocks generated from a further batch of physical layer packets are illustrated at 924, and 926 illustrates transmitting and receiving associated VCBs. Encoding for the code blocks at 924 is not illustrated in FIG. 9 to avoid congestion in the drawing. 922 illustrates that methods may involve transmitting and/or receiving encoding information for further CBs, if encoding information is different for different batches.

Embodiments may, but need not necessarily, involve feedback between CB and VCB transmissions. This is indicated in FIG. 9 by the dashed line for feedback at 918, and the absence of an explicit feedback operation between 924, 926.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor and a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to, or to cause a processor to, transmit, to a receiving device in a wireless communication network, CBs generated based on a batch of physical layer packets to which a subset of higher-layer encoded packets are mapped. The higher-layer encoded packets are generated from higher-layer information packets, and packets of the higher-layer information packets that are used to generate the subset of higher-layer encoded packets for the batch overlap with packets of the higher layer information packets that are used to generate a further subset of the higher-layer encoded information packets for mapping to a further batch of physical layer packets. The programming also includes instructions to, or to cause a processor to, transmit check blocks to the receiving device. Each check block is generated based on portions of multiple CBs.

Embodiments related to apparatus or non-transitory computer readable storage media for a transmitting device or transmit-side operations may include any one or more of the following features, for example, which are also discussed elsewhere herein:
the programming further includes instructions to, or to cause a processor to, transmit to the receiving device further CBs generated based on the further batch of physical layer packets;
the programming further includes instructions to, or to cause a processor to, transmit further check blocks to the receiving device, each further check block generated based on portions of multiple CBs of the further CBS;
the higher-layer encoded packets having been generated based on a higher-layer erasure code applied to the higher-layer information packets;
the packets of the higher-layer information packets that are used to generate the further subset of higher-layer encoded packets include a further subset of the higher-layer information packets;
the subset and the further subset of the higher-layer information packets, from which the subset and the further subset of the higher-layer encoded packets are generated, are different from and overlapping with each other;
the subset of the higher-layer information packets includes a first number d1 of the higher-layer information packets;
the further subset of the higher-layer information packets includes a second number d2 of the higher-layer information packets;
either or both of d1 and d2 are sampled from a degree distribution;
either or both of the d1 and d2 higher-layer information packets in the subset and the further subset of the higher-layer information packets are randomly selected from the higher-layer information packets;
the subset of the higher-layer encoded packets having been generated based on linear combinations of the subset of the higher-layer information packets;
the programming further includes instructions to, or to cause a processor to, transmit coefficients for the linear combinations to the receiving device;
the programming including instructions to transmit the CBs by transmitting information bits of the CBs and respective check blocks for the CBs, the check block for each CB having been generated based on a first code applied to the information bits of the CB;
the check blocks based on the portions of the multiple CBs having been generated based on a second code applied to the portions of the multiple CBs;
each of the higher-layer encoded packets maps to one of the physical layer packets (or a part thereof) based on which a transport block comprising one or more of the CBs is generated;
each of the higher-layer encoded packets maps to one of the physical layer packets (or a part thereof) based on which one of the CBs is generated;
each of the higher-layer encoded packets maps to one of the physical layer packets (or a part thereof) based on which one of the portions of the multiple CBs is generated;
each of the CBs is or includes subblocks;
each of the higher-layer encoded packets maps to one of the physical layer packets (or a part thereof) based on which one of the subblocks is generated;
the portions of multiple CBs based which each check block is generated are or include a subblock of each of the multiple CBs;
the programming further includes instructions to, or to cause a processor to, transmit to the receiving device multiple sets of check blocks generated based on different combinations of the portions of the multiple CBS;
the programming includes instructions to, or to cause a processor to, transmit a respective one of the multiple sets of check blocks based on receiving negative feedback from the receiving device for at least one of the physical layer packets of the batch of physical layer packets;
the programming further including instructions to, or to cause a processor to, transmit to the receiving device, based on receiving positive feedback from the receiving device for all of the physical layer packets of the batch of physical layer packets, code blocks generated from the further batch of physical layer packets;
the programming further including instructions to, or to cause a processor to, transmit to the receiving device, based on a maximum number of transmissions of sets of check blocks, code blocks generated from the further batch of physical layer packets.

These and other features are also described elsewhere herein, at least in the context of method embodiments, and may also or instead be implemented in apparatus embodiments and/or computer-readable medium embodiments.

Programming stored in or on a non-transitory computer readable storage medium may also or instead include instructions to, or to cause a processor to, receive, from a transmitting device in a wireless communication network, CBs generated based on a batch of physical layer packets to which a subset of higher-layer encoded packets are mapped. The higher-layer encoded packets are generated from higher-layer information packets, and packets of the higher-layer information packets that are used to generate the subset of higher-layer encoded packets for the batch overlap with packets of the higher layer information packets that are used to generate a further subset of the higher-layer encoded information packets for mapping to a further batch of physical layer packets. The programming also includes instructions to, or to cause a processor to, transmit check blocks to the receiving device. Each check block is generated based on portions of multiple CBs.

Embodiments related to apparatus or non-transitory computer readable storage media for a receiving device or receive-side operations may include any one or more of the following features, for example, which are also discussed elsewhere herein:
the programming further includes instructions to, or to cause a processor to, receive from the transmitting device further CBs generated based on the further batch of physical layer packets;
the programming further includes instructions to, or to cause a processor to, receive further check blocks from the transmitting device, each further check block generated based on portions of multiple CBs of the further CBS;
the higher-layer encoded packets having been generated based on a higher-layer erasure code applied to the higher-layer information packets;
the packets of the higher-layer information packets that are used to generate the further subset of higher-layer encoded packets include a further subset of the higher-layer information packets;
the subset and the further subset of the higher-layer information packets, from which the subset and the further subset of the higher-layer encoded packets are generated, are different from and overlapping with each other;
the subset of the higher-layer information packets includes a first number d1 of the higher-layer information packets;
the further subset of the higher-layer information packets includes a second number d₂ of the higher-layer information packets;
either or both of d₁ and d₂ are sampled from a degree distribution;
either or both of the d₁ and d₂ higher-layer information packets in the subset and the further subset of the higher-layer information packets are randomly selected from the higher-layer information packets;
the subset of the higher-layer encoded packets having been generated based on linear combinations of the subset of the higher-layer information packets;
the programming further includes instructions to, or to cause a processor to, receive coefficients for the linear combinations from the transmitting device;
the programming includes instructions to receive the CBs by receiving information bits of the CBs and respective check blocks for the CBs, the check block for each CB having been generated based on a first code applied to the information bits of the CB;
the check blocks based on the portions of the multiple CBs having been generated based on a second code applied to the portions of the multiple CBS;
each of the higher-layer encoded packets maps to one of the physical layer packets (or a part thereof) based on which a transport block comprising one or more of the CBs is generated;
each of the higher-layer encoded packets maps to one of the physical layer packets (or a part thereof) based on which one of the CBs is generated;
each of the higher-layer encoded packets maps to one of the physical layer packets (or a part thereof) based on which one of the portions of the multiple CBs is generated;
each of the CBs is or includes subblocks;
each of the higher-layer encoded packets maps to one of the physical layer packets (or a part thereof) based on which one of the subblocks is generated;
the portions of multiple CBs based which each check block is generated are or include a subblock of each of the multiple CBS;
the programming further includes instructions to, or to cause a processor to, receive from the transmitting device multiple sets of check blocks generated based on different combinations of the portions of the multiple CBS;
the programming includes instructions to, or to cause a processor to, receive a respective one of the multiple sets of check blocks based on transmitting negative feedback to the transmitting device for at least one of the physical layer packets of the batch of physical layer packets;
the programming further including instructions to, or to cause a processor to, receive from the transmitting device, based on transmitting positive feedback from the receiving device to the transmitting device for all of the physical layer packets of the batch of physical layer packets, code blocks generated from the further batch of physical layer packets;
the programming further including instructions to, or to cause a processor to, receive from the transmitting device, based on a maximum number of transmissions of sets of check blocks by the transmitting device, code blocks generated from the further batch of physical layer packets.

These and other features are also described elsewhere herein, at least in the context of method embodiments, and may also or instead be implemented in apparatus embodiments and/or computer-readable medium embodiments.

Various embodiments are disclosed by way of example herein. Examples of possible application scenarios for any of these embodiments, or others, are provided below. Although embodiments may be implemented for unicast applications, the following example applications may be more compelling.

Large file multicast or large packet multicast may be an attractive application for embodiments disclosed herein. In a multicast scenario, cross-CB coding is applied on each batch on PHY packets, and no feedback is required for each batch to be decoded successfully. Cross-CB coding applied to each batch can take advantage of a 2D HARQ scheme (soft decoding, for example) without very high complexity. Batches of higher-layer encoded packets and PHY packets are linked from a higher-layer code, and thus each batch does not need to be entirely decoded by every receiver, which can reduce the need for feedback and make link adaptation more flexible, with enhanced reliability as a result of the higher-layer code.

Network coding-based cooperation is another example application. In a butterfly network, for example, a UE can combine packets from two other UEs to produce cross-CB based coding. Some methods for application of cross-CB coding in network coding without a batch-based approach can be found in US 2021/0297180 A1, referenced above, and details of such methods are not repeated herein to avoid congestion of text. With a batch-based approach, this type of combination of packets can be operated on a per-batch basis as described in the present disclosure. Cooperation nodes then need only combine 2D code from the same batch in order to decode the batch. This gives similar advantage of batch-based cross-CB coding in other applications, including reduced complexity, and high decoding performance from cross-CB coding, and does not require each batch to be always decoded successfully.

Potential benefits of disclosed embodiments may include any one or more of the following:
the same advantage of higher-layer rateless codes but with performance advantage of cross-CB coding;
reduced decoding complexity compare to PHY layer cross-CB rateless coding;
practical network coding scheme that can be applied to large packet multicast, network coding based cooperation, for example;
partial recovery without decoding of a full batch of PHY packets can contribute to global higher-layer code decoding;
with subblock interleaving, a subblock can be the minimum decoding unit for cross-CB coding and higher-layer coding;
a complete PHY solution, in the sense that a physical layer transmission procedure in wireless channels may be provided, unlike traditional network coding schemes with assumption of erasure channels in which it is assumed that a packet either arrives or is lost.

A batch-based cross-CB coding approach with a higher-layer erasure code that is similar to a Fountain code, or rateless code, as a higher-layer code may be preferred to provide potential benefits such as any one or more of the following, for example: maintaining degree distribution for higher-layer code design, enabling subblocks as minimum decoding units for cross-CB coding, and enabling partial decoding from a cross-CB code that still benefits a higher-layer code. The example higher layer erasure code described in this disclosure can be used as rateless code, thus, the encoder for the higher layer code can produce as many higher layer encoded information packets as needed or desired in a particular application, and thus the number of batches that is produced can also be limitness and determined based on needs or targets. For example, the number of higher layer encoded packets and correspondingly the number of batches can be fixed based on a predetermined code rate for the higher layer code or alternatively, the higher layer code can keep generating higher layer encoded packets or batches until a positive feedback is received for successfully decoding all the higher layer information packets.

Although this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

Features disclosed herein in the context of method embodiments, for example, may also or instead be implemented in apparatus or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

1. A method comprising:
transmitting, to a receiving device in a wireless communication network, a plurality of code blocks (CBs) generated based on a batch of physical layer packets to which a subset of higher-layer encoded packets, generated from higher-layer information packets, are mapped, wherein first packets of the higher-layer information packets that are used to generate the subset of higher-layer encoded packets for the batch overlap with second packets of the higher-layer information packets that are used to generate a further subset of the higher-layer encoded packets for mapping to a further batch of physical layer packets; and
transmitting, to the receiving device, a plurality of check blocks, each check block of the plurality of check blocks generated based on portions of multiple CBs of the plurality of CBs.

2. The method of claim 1, wherein the method further comprises:
transmitting, to the receiving device, further CBs generated based on the further batch of physical layer packets; and
transmitting, to the receiving device, further check blocks, each further check block of the further check blocks generated based on portions of multiple CBs of the further CBs.

3. The method of claim 1, the higher-layer encoded packets having been generated based on a higher-layer erasure code applied to the higher-layer information packets.

4. The method of claim 1, wherein:
the first packets comprise a subset of the higher-layer information packets,
the second packets comprise a further subset of the higher-layer information packets, and
the subset of the higher-layer information packets and the further subset of the higher-layer information packets, from which the subset of the higher-layer encoded information packets and the further subset of the higher-layer encoded information packets are generated, respectively, are different from and overlap with each other.

5. The method of claim 4, wherein:
the subset of the higher-layer information packets includes a first number (d₁) of the higher-layer information packets,
the further subset of the higher-layer information packets includes a second number (d₂) of the higher-layer information packets,
d₁ and d₂ are sampled from a degree distribution, and
the first number of higher-layer information packets and the second number of higher-layer information packets in the subset of the higher-layer information packets and the further subset of the higher-layer information packets, respectively, are randomly selected from the higher-layer information packets.

6. An apparatus comprising:
at least one processor; and
a non-transitory computer readable storage medium, coupled to the at least one processor, storing programming for execution by the at least one processor, the programming including instructions to cause the apparatus to perform operations including:
transmitting, to a receiving device in a wireless communication network, a plurality of code blocks (CBs) generated based on a batch of physical layer packets to which a subset of higher-layer encoded packets, generated from higher-layer information packets, are mapped, wherein first packets of the higher-layer information packets that are used to generate the subset of higher-layer encoded packets for the batch overlap with second packets of the higher-layer information packets that are used to generate a further subset of the higher-layer encoded information packets for mapping to a further batch of physical layer packets; and
transmitting, to the receiving device, a plurality of check blocks, each check block of the plurality of check blocks generated based on portions of multiple CBs of the plurality of CBs.

7. The apparatus of claim 6, the operations further comprising:
transmitting, to the receiving device, further CBs generated based on the further batch of physical layer packets; and
transmitting, to the receiving device, further check blocks, each further check block of the further check blocks generated based on portions of multiple CBs of the further CBs.

8. The apparatus of claim 6, the higher-layer encoded packets having been generated based on a higher-layer erasure code applied to the higher-layer information packets.

9. The apparatus of claim 6, wherein:
the first packets comprise a subset of the higher-layer information packets,
the second packets comprise a further subset of the higher-layer information packets, and
the subset of the higher-layer information packets and the further subset of the higher-layer information packets, from which the subset of the higher-layer encoded information packets and the further subset of the higher-layer encoded packets are generated, respectively, are different from and overlap with each other.

10. The apparatus of claim 9, wherein:
the subset of the higher-layer information packets includes a first number (d₁) of the higher-layer information packets,
the further subset of the higher-layer information packets includes a second number (d₂) of the higher-layer information packets,
d₁ and d₂ are sampled from a degree distribution, and
the first number of higher-layer information packets and the second number of higher-layer information packets in the subset of the higher-layer information packets and the further subset of the higher-layer information packets, respectively, are randomly selected from the higher-layer information packets.

11. A method comprising:
receiving, from a transmitting device in a wireless communication network, a plurality of code blocks (CBs) generated based on a batch of physical layer packets to which a subset of higher-layer encoded packets, generated from higher-layer information packets, are mapped, wherein first packets of the higher-layer information packets that are used to generate the subset of higher-layer encoded packets for the batch overlap with second packets of the higher-layer information packets that are used to generate a further subset of the higher-layer encoded packets for mapping to a further batch of physical layer packets; and
receiving, from the transmitting device, a plurality of check blocks, each check block of the plurality of check blocks generated based on portions of multiple CBs of the plurality of CBs.

12. The method of claim 11, wherein the method further comprises:
receiving, from the transmitting device, further CBs generated based on the further batch of physical layer packets; and
receiving, from the transmitting device, further check blocks, each further check block of the further check blocks generated based on portions of multiple CBs of the further CBs.

13. The method of claim 11, the higher-layer encoded packets having been generated based on a higher-layer erasure code applied to the higher-layer information packets.

14. The method of claim 11, wherein:
the first packets comprise a subset of the higher-layer information packets,
the second packets comprise a further subset of the higher-layer information packets, and
the subset of the higher-layer information packets and the further subset of the higher-layer information packets, from which the subset of the higher-layer encoded information packets and the further subset of the higher-layer encoded packets are generated, respectively, are different from and overlap with each other.

15. The method of claim 14, wherein:
the subset of the higher-layer information packets includes a first number (d₁) of the higher-layer information packets,
the further subset of the higher-layer information packets includes a second number (d₂) of the higher-layer information packets,
d₁ and d₂ are sampled from a degree distribution, and
the first number of higher-layer information packets and the second number of higher-layer information packets in the subset of the higher-layer information packets and the further subset of the higher-layer information packets, respectively, are randomly selected from the higher-layer information packets.

16. An apparatus comprising:
at least one processor; and
a non-transitory computer readable storage medium, coupled to the at least one processor, storing programming for execution by the at least one processor, the programming including instructions to cause the apparatus to perform operations including:
receiving, from a transmitting device in a wireless communication network, a plurality of code blocks (CBs) generated based on a batch of physical layer packets to which a subset of higher-layer encoded packets, generated from higher-layer information packets, are mapped, wherein first packets of the higher-layer information packets that are used to generate the subset of higher-layer encoded packets for the batch overlap with second packets of the higher-layer information packets that are used to generate a further subset of the higher-layer encoded packets for mapping to a further batch of physical layer packets; and
receiving, from the transmitting device, a plurality of check blocks, each check block generated based on portions of multiple CBs of the plurality of CBs.

17. The apparatus of claim 16, the operations further comprising:
receiving, from the transmitting device, further CBs generated based on the further batch of physical layer packets; and
receiving, from the transmitting device, further check blocks, each further check of the further check blocks block generated based on portions of multiple CBs of the further CBs.

18. The apparatus of claim 16, the higher-layer encoded packets having been generated based on a higher-layer erasure code applied to the higher-layer information packets.

19. The apparatus of claim 16, wherein:
the first packets comprise a subset of the higher-layer information packets,
the second packets comprise a further subset of the higher-layer information packets, and
the subset of the higher-layer information packets and the further subset of the higher-layer information packets, from which the subset of the higher-layer encoded information packets and the further subset of the higher-layer encoded packets are generated, respectively, are different from and overlap with each other.

20. The apparatus of claim 19, wherein:
the subset of the higher-layer information packets includes a first number (d₁) of the higher-layer information packets,
the further subset of the higher-layer information packets includes a second number (d₂) of the higher-layer information packets,
d₁ and d₂ are sampled from a degree distribution, and
the first number of higher-layer information packets and the second number of higher-layer information packets in the subset and the further subset of the higher-layer information packets are randomly selected from the higher-layer information packets.
